(19) United States
(12) Patent Application Publication
(10) Pub. No.: US 2026/0118775 A1
(43) Pub. Date: Apr. 30, 2026

(54) EXPOSURE APPARATUS, EXPOSURE METHOD, AND ARTICLE MANUFACTURING METHOD

(71) Applicant: CANON KABUSHIKI KAISHA, Tokyo (JP)

(72) Inventor: TAKANORI SATO, Tochigi (JP)

(21) Appl. No.: 19/364,101

(22) Filed: Oct. 21, 2025

(30) Foreign Application Priority Data
Oct. 29, 2024 (JP) 2024-190074

(51) Int. Cl. G03F 7/00

(52) U.S. Cl. CPC G03F 7/70725; G03F 7/70358; G03F 7/70525; G03F 7/70775; G03F 7/7085

(57) ABSTRACT

The present disclosure provides an exposure apparatus that performs scanning exposure to a shot region on a substrate, comprising: a stage configured to hold the substrate; a measurement device configured to measure a surface height prior to exposure for each of a plurality of measurement regions arrayed in the shot region along a scanning direction of the substrate; and a controller configured to control driving of the stage, wherein the plurality of measurement regions include a first and second measurement regions, and wherein the controller is configured to control, based on measurement values of surface heights for the first and second measurement regions, driving of the stage to arrange the surface height of the first measurement region at a target height in exposure of the first measurement region.

### BACKGROUND

### Field of the Technology

The present disclosure relates to an exposure apparatus, an exposure method, and an article manufacturing method.

### Description of the Related Art

In a manufacturing process for a semiconductor device or the like, an exposure apparatus that performs scanning exposure of a substrate by scanning the substrate with respect to light having passed through an original can be used as a lithography apparatus that forms a pattern on a substrate. In such an exposure apparatus, while measuring the surface height of a substrate prior to exposure, driving of a stage that holds the substrate is controlled to arrange the surface height of the substrate at a target height (for example, the focus position of a projection optical system) based on the measurement value.

Japanese Patent Laid-Open No. 9-246356 has described a method of measuring the height of a substrate surface at a predetermined time interval, and determining a driving command value for a stage based on the measurement value. More specifically, the surface height of a position N on a substrate is measured, and a driving command value when exposing the position N is determined based on the measurement value. Similarly, the surface height of a position (N+1) on the substrate is measured, and a driving command value when exposing the position (N+1) is determined based on the measurement value. In addition, a driving command value between the position N and the position (N+1) is determined by interpolating the driving command value determined for the position N and the driving command value determined for the position (N+1).

Recently, along with a request for higher productivity, an exposure apparatus needs to shorten the time taken for scanning exposure by increasing the scanning speed of a substrate. However, if the scanning speed of a substrate is increased, the measurement time to measure the surface height of each position (region) on a substrate prior to exposure is shortened, and the measurement accuracy may decrease. In this case, if a driving command value when exposing the position N on a substrate is determined based on only the measurement value of the surface height of the position N, like the method described in Japanese Patent Laid-Open No. 9-246356, it becomes difficult to accurately arrange the surface height of the position N at the target height. That is, the pattern formation accuracy may decrease.

### SUMMARY

The present disclosure provides a technique advantageous for productivity and pattern formation accuracy in an exposure apparatus.

According to one aspect of the present disclosure, there is provided an exposure apparatus that performs scanning exposure to a shot region on a substrate, comprising: a stage configured to hold the substrate; a measurement device configured to measure a surface height prior to exposure for each of a plurality of measurement regions arrayed in the shot region along a scanning direction of the substrate; and a controller configured to control driving of the stage, wherein the plurality of measurement regions include a first measurement region, and a second measurement region for which the measurement device measures a surface height after measurement of a surface height for the first measurement region and before exposure of the first measurement region, and wherein the controller is configured to control, based on measurement values of surface heights for the first measurement region and the second measurement region obtained by the measurement device, driving of the stage to arrange the surface height of the first measurement region at a target height in exposure of the first measurement region.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing a configuration example of an exposure apparatus;

FIG. 2 is a view showing the positional relationship between a shot region, a light irradiation region, and a plurality of measurement points;

FIG. 3A is a view for explaining scanning exposure to respective shot regions;

FIG. 3B is a view for explaining scanning exposure to respective shot regions;

FIG. 4 is a graph showing the relationship between the scanning speed of a substrate, the measurement time, and the measurement dispersion;

FIG. 5 is a view showing a plurality of measurement regions arrayed in a shot region;

FIG. 6 is a graph for explaining a control example of driving of a substrate stage in the first embodiment;

FIG. 7 is a graph for explaining a control example of driving of a substrate stage in Example 1 of the second embodiment;

FIG. 8 is a graph for explaining a control example of driving of the substrate stage in Example 2 of the second embodiment;

FIG. 9 is a graph for explaining a control example of driving of the substrate stage in Example 3 of the second embodiment;

FIG. 10 is a view showing a plurality of measurement regions arrayed in a shot region;

FIG. 11 is a flowchart showing exposure processing; and

FIG. 12 is a plan view of a substrate showing portions (sample shot regions) subjected to surface height measurement.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which the image plane (focus plane) of a projection optical system is defined as an X-Y plane. Directions parallel to the X-axis, Y-axis, and Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving (movement) concerning the X-axis, the Y-axis, and the Z-axis means control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

### First Embodiment

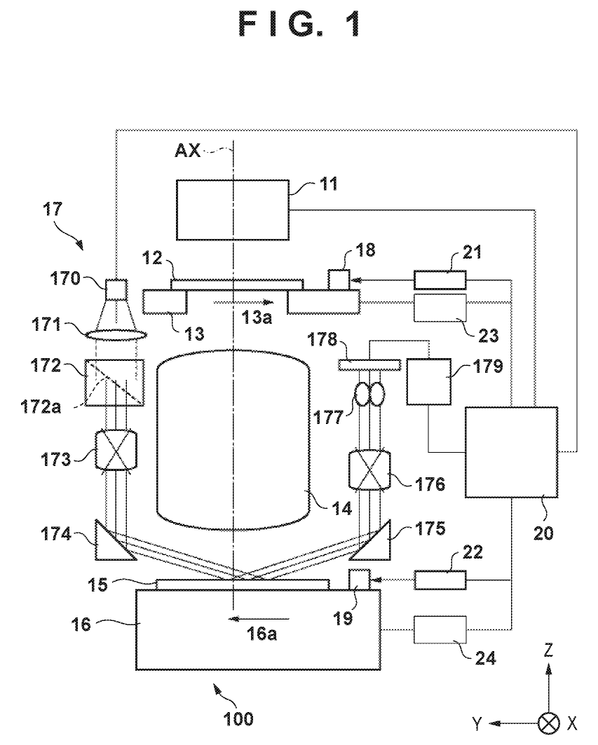

The first embodiment according to the present disclosure will be explained. FIG. 1 is a schematic view showing a configuration example of an exposure apparatus 100 according to this embodiment. The exposure apparatus 100 relatively scans and drives an original 12 and a substrate 15 with respect to exposure light (slit light) having a rectangular or arc-like sectional shape, thereby performing scanning exposure of the substrate 15 and transferring the pattern of the original 12 to the substrate 15. The exposure apparatus 100 of this type is also called a step-and-scan exposure apparatus or a scanner.

As shown in FIG. 1, the exposure apparatus 100 includes an illumination optical system 11, an original stage 13, a projection optical system 14, a substrate stage 16, a measurement device 17, and a controller 20. The original stage 13 and the substrate stage 16 can constitute a driving mechanism for relatively scanning the original 12 and the substrate 15 via the projection optical system 14.

The illumination optical system 11 illuminates the original 12 using light emitted from a light source (not shown) that generates pulsed light, such as an excimer laser. The illumination optical system 11 includes, for example, a beam shaping optical system, an optical integrator, a collimator lens, and a mirror. The illumination optical system 11 efficiently transmits or reflects pulsed light of the far ultraviolet region, and emits it as exposure light (slit light). The beam shaping optical system includes a mechanism (for example, a slit) that shapes the sectional shape (dimensions) of incident light into a predetermined shape (for example, a rectangular or arc-like shape). The beam shaping optical system generates exposure light (slit light) using light from the light source. The exposure light has a sectional shape that defines an illumination region on the original 12, that is, a light irradiation region on the substrate 15. In this embodiment, the beam shaping optical system is configured to generate exposure light having a rectangular sectional shape using light from the light source. The optical integrator uniforms the distribution characteristic of light, and illuminates the original 12 at a uniform illuminance.

The projection optical system 14 projects, onto the substrate 15, the pattern image of the original 12 illuminated by the illumination optical system 11. In FIG. 1, an optical axis AX of the projection optical system 14 extends in the Z direction, and the image plane of the projection optical system 14 is a plane (that is, an X-Y plane) perpendicular to the Z direction. Exposure light traveling from the illumination optical system 11 irradiates the original 12, and the pattern image of the original 12 is formed on the image plane of the projection optical system 14 at the projection magnification (for example, 1/4, 1/2, or 1/5) of the projection optical system 14.

The substrate 15 is, for example, a wafer coated with a resist (photoresist) on the surface. On the substrate 15, a plurality of shot regions having the same pattern structure formed by preceding lithography processing are arrayed. The substrate stage 16 is a stage that moves while holding the substrate 15, and includes a chuck that holds (chucks and fixes) the substrate 15. The substrate stage 16 is driven by a substrate driving mechanism 24. The substrate stage 16 can include an X-Y stage horizontally movable respectively in the X and Y directions, and a Z stage movable in the Z direction (direction of height of the substrate 15) parallel to the optical axis AX of the projection optical system 14. Further, the substrate stage 16 can include even a leveling stage rotatable (inclinable) in the θX direction about the X-axis and the θY direction about the Y-axis, and a rotation stage rotatable in the θZ direction about the Z-axis. In this manner, the substrate stage 16 can constitute a six-axis driving system for making the pattern image of the original 12 coincide with a shot region of the substrate 15. Positions of the substrate stage 16 in the X, Y, and Z directions can always be measured by a bar mirror 19 arranged on the substrate stage 16, and an interferometer 22.

The original 12 (mask or reticle) has a pattern to be transferred to each of shot regions on the substrate 15, and is held by the original stage 13. The original stage 13 is driven by an original driving mechanism 23, and is scanned in a predetermined direction (for example, the Y direction) within a plane perpendicular to the optical axis AX of the projection optical system 14. At this time, the original stage 13 is scanned so that a position of the original stage 13 in the Y direction always maintains a target position. Positions of the original stage 13 in the X and Y directions can always be measured by a bar mirror 18 arranged on the original stage 13, and an interferometer 21.

The measurement device 17 measures the surface height (surface position) of the substrate 15. In this embodiment, the measurement device 17 is configured to measure the surface height of the substrate 15 prior to exposure (irradiation with exposure light) for each of measurement regions arrayed on the substrate 15 in the scanning direction in a state in which the substrate 15 (substrate stage 16) moves. As shown in FIG. 1, the measurement device 17 according to this embodiment is of an oblique incidence type in which the substrate 15 is irradiated obliquely with light. The measurement device 17 includes an irradiation system that irradiates the substrate 15 with light, and a light receiving system that receives light reflected by the substrate 15. Note that measurement of the surface height of the substrate 15 by the measurement device 17 will be sometimes referred to as "focus measurement" hereinafter.

The irradiation system of the measurement device 17 can include, for example, a light source 170, a collimator lens 171, a slit member 172, an optical system 173, and a mirror 174. The light source 170 is constituted by, for example, a white lamp or a high-luminance light-emitting diode having a plurality of different peak wavelengths, and emits light (measurement light) used to measure the surface height of the substrate 15. The measurement light emitted from the light source 170 is preferably light of a wavelength to which a resist on the substrate 15 is not sensitive. The collimator lens 171 collimates light emitted from the light source 170 into a parallel beam having an substantially uniform light intensity distribution of a section. The slit member 172 is constituted by a pair of prisms bonded so that their inclined surfaces face each other. On a bonded surface 172a, a light-shielding film of chrome or the like having a plurality of openings (for example, nine pinholes) is provided. The optical system 173 is a bi-telecentric optical system, and causes a plurality of (for example, nine) beams having passed through a plurality of openings of the slit member 172 (bonded surface 172a) to enter the substrate 15 via the mirror 174. The optical system 173 is constituted so that a plane on which the openings are formed, and a plane including the surface of the substrate 15 satisfy the Scheimpflug condition. By entering a plurality of beams to the substrate 15, focus measurement can be performed individually for respective measurement regions on the substrate.

The light receiving system of the measurement device 17 can include, for example, a mirror 175, a light receiving optical system 176, a correction optical system 177, a photoelectric converter 178, and a processor 179. The mirror 175 guides a plurality of beams reflected by the substrate 15 to the light receiving optical system 176. The light receiving optical system 176 is a bi-telecentric optical system, and includes a stopper provided commonly to a plurality of beams. The stopper included in the light receiving optical system 176 cuts off high-order diffraction light (noise light) generated owing to a circuit pattern formed on the substrate 15. The correction optical system 177 includes a plurality of (for example, nine) lenses in correspondence with a plurality of beams. The correction optical system 177 images a plurality of beams on the light receiving surface of the photoelectric converter 178, thereby forming pinhole images on the light receiving surface. The photoelectric converter 178 includes a plurality of (for example, nine) photoelectric converters in correspondence with a plurality of beams. As the photoelectric converter, for example, a one-dimensional line sensor or a two-dimensional sensor constituted by a CCD sensor, a CMOS sensor, or the like can be used. The processor 179 calculates the surface height of each measurement region on the substrate 15 based on the position of each pinhole image on the light receiving surface of the photoelectric converter 178.

The controller 20 is constituted by, for example, a computer including a processor such as a Central Processing Unit (CPU), and a storage such as a memory. The controller 20 comprehensively controls the respective units of the exposure apparatus 100 to control scanning exposure of the substrate 15. For example, the controller 20 controls driving of the original stage 13 and driving of the substrate stage 16 respectively by the original driving mechanism 23 and the substrate driving mechanism 24 so as to form an image on the substrate 15 (shot region) from exposure light having passed through the original 12. The controller 20 can adjust the relative positions of the original 12 and substrate 15 by controlling relative driving of the original stage 13 and substrate stage 16.

The controller 20 scans the original stage 13 and the substrate stage 16 in synchronization with the projection optical system 14. Thus, the controller 20 can control scanning exposure (exposure processing) to expose each shot region of the substrate 15 while scanning the substrate 15 with respect to exposure light by the substrate stage 16. For example, the controller 20 scans and drives the substrate stage 16 (substrate 15) in the direction of an arrow 16a at a velocity ratio corresponding to the projection magnification of the projection optical system 14 while scanning and driving the original stage 13 (original 12) in the direction of an arrow 13a. The scanning speed of the original stage 13 can be determined to be advantageous for productivity (throughput) based on the width of a masking blade in the scanning direction in the illumination optical system 11, and the sensitivity of a resist applied to the surface of the substrate 15 (or the intensity of exposure light irradiating the substrate 15).

Here, alignment of the pattern of the original 12 in the X-Y plane can be performed based on the position of the original stage 13, that of the substrate stage 16, and that of each shot region of the substrate 15 with respect to the substrate stage 16. As described above, the position of the original stage 13 and that of the substrate stage 16 are measured by the interferometer 21 and the interferometer 22, respectively. The position of each shot region of the substrate 15 with respect to the substrate stage 16 is obtained by detecting the position of a mark provided on the substrate stage 16 and that of an alignment mark formed on the substrate 15 by an alignment detector (not shown).

The controller 20 performs focus leveling control (also called focus leveling driving) of the substrate 15 based on the measurement result of the measurement device 17. Focus leveling control is to control at least either of the height (position in the Z direction) and inclination (tilt in the θX and θY directions) of the substrate 15 by the substrate stage 16. A target height can be set at, for example, the best focus position (image plane position of the projection optical system 14) of the projection optical system 14. In this embodiment, the controller 20 sequentially executes focus leveling control of the substrate 15 based on the measurement value of the surface height of the substrate 15 obtained by the measurement device 17 while measuring the surface height of the substrate 15 by the measurement device 17 in scanning exposure of the substrate 15 (each shot region). Note that an example of controlling the height of the substrate 15 will be explained below as focus leveling control.

FIG. 2 shows the positional relationship between a target shot region 15a subjected to scanning exposure, a light irradiation region 30 irradiated with exposure light traveling from the projection optical system 14, and a plurality of measurement points 31 to 33 subjected to focus measurement (measurement of the surface height) by the measurement device 17. The measurement device 17 according to this embodiment is configured to measure the surface height of the shot region 15a at each of nine measurement points 31 to 33. In FIG. 2, the light irradiation region 30 is a rectangular region surrounded by a broken line. The measurement points 31, that is, 31a to 31c are measurement points at which the measurement device 17 performs focus measurement inside the light irradiation region 30. The measurement points 32, that is, 32a to 32c and the measurement points 33, that is, 33a to 33c are measurement points at which the measurement device 17 performs focus measurement prior to exposure in the light irradiation region 30. The measurement points 32 and the measurement points 33 are arranged at positions apart by a distance Lp in the scanning direction (±Y direction) from the measurement points 31 within the light irradiation region 30. Focus measurement performed at the measurement points 32 or the measurement points 33 prior to exposure in the light irradiation region 30 will be sometimes referred to as "pre-reading measurement" hereinafter. Note that the measurement points 31, the measurement points 32, and the measurement points 33 in this embodiment each include three measurement points arrayed in a direction (X direction) crossing the scanning direction (Y direction), but are not limited to this and may include two measurement points or four or more measurement points.

In the measurement device 17 having this configuration, the measurement points 32 and 33 used for pre-reading measurement are switched in accordance with the scanning direction (moving direction) of the substrate 15. For example, when performing scanning exposure of the shot region 15a while scanning the substrate 15 in a direction F, the measurement points 32 are used for pre-reading measurement. In this case, the controller 20 controls driving of the substrate stage 16 in the direction of height (Z direction) based on measurement values at the measurement points 32 so that a substrate surface in the light irradiation region 30 is arranged on the best focus plane (imaging plane or image plane) of the projection optical system 14. In contrast, when performing scanning exposure of the shot region 15a while scanning the substrate 15 in a direction R, the measurement points 33 are used for pre-reading measurement. In this case, the controller 20 controls driving of the substrate stage 16 in the direction of height based on measurement values at the measurement points 33 so that a substrate surface in the light irradiation region 30 is arranged on the image plane of the projection optical system 14.

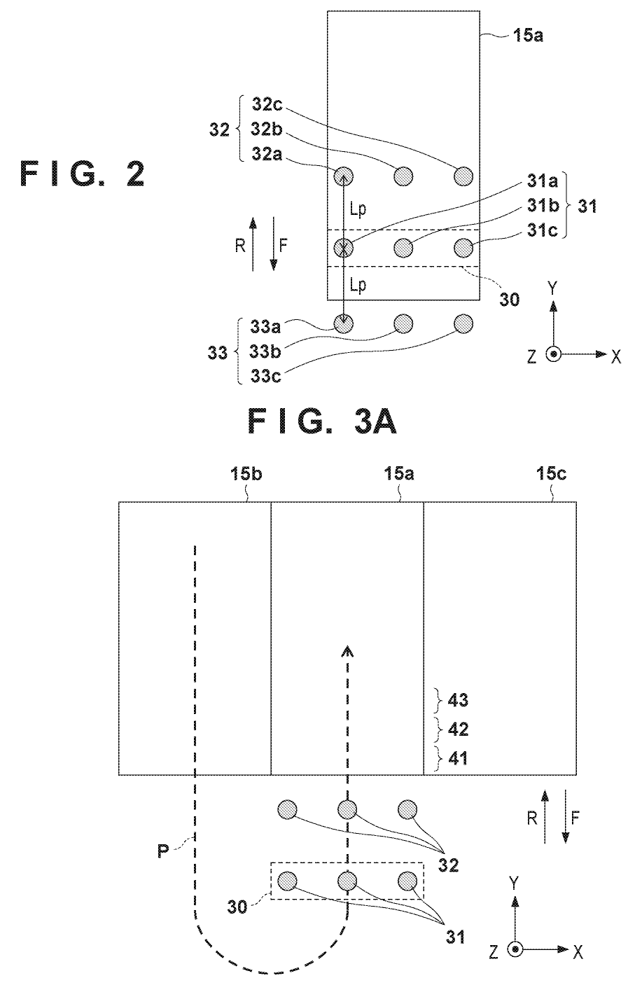

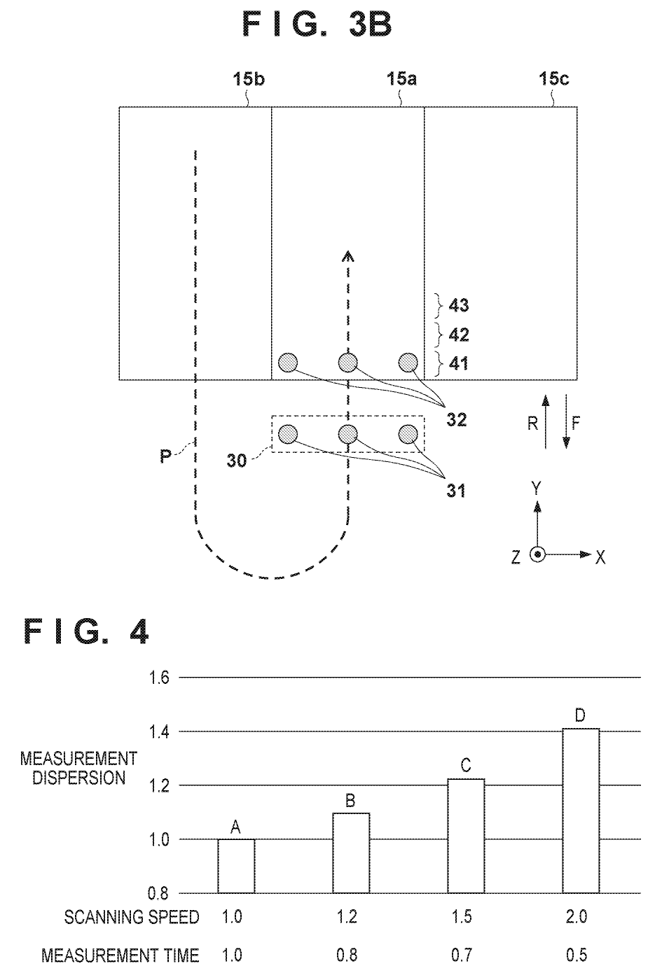

FIGS. 3A and 3B are views for explaining scanning exposure in each of a plurality of shot regions 15a to 15c on the substrate 15. The shot region 15a is a target shot region to undergo scanning exposure from now. The shot region 15b is a shot region having undergone scanning exposure before the shot region 15a. The shot region 15c is a shot region to undergo scanning exposure next to the shot region 15a. FIGS. 3A and 3B show the light irradiation region 30, and the measurement points 31 and 32 for which the measurement device 17 performs focus measurement. In FIGS. 3A and 3B, a moving path P of the light irradiation region 30 and measurement points 31 to 32 on the substrate 15 is indicated by an arrow of a broken line.

In response to the end of scanning exposure in the shot region 15b, the controller 20 moves step by step the substrate stage 16 in the X direction in order to perform scanning exposure in the next shot region 15a while decelerating the substrate stage 16 (substrate 15) moving in the direction R. FIG. 3A shows a state before the start of pre-reading measurement of the shot region 15a at the measurement points 32 by the measurement device 17 after the end of scanning exposure in the shot region 15b. In the shot region 15a, a plurality of measurement regions 41 to 43 to undergo pre-reading measurement in order at the measurement points 32 by the measurement device 17 prior to exposure in the light irradiation region 30 are arrayed (set) in the scanning direction (Y direction) of the substrate 15. For example, the measurement region 41 is a measurement region arranged at an end of the shot region 15a where scanning exposure starts, and to undergo pre-reading measurement first at the measurement points 32 of the measurement device 17 among the measurement regions 41 to 43. Here, only three measurement regions 41 to 43 are set in the shot region 15a in FIG. 3A to simplify the illustration, but a larger number of measurement regions can be set in the shot region 15a.

Then, the controller 20 accelerates the substrate stage 16 in the direction F in order to start scanning exposure in the shot region 15a. FIG. 3B shows a state in which pre-reading measurement of the shot region 15a at the measurement points 32 by the measurement device 17 starts, that is, a state in which pre-reading measurement is performed in the measurement region 41 of the shot region 15a at the measurement points 32 of the measurement device 17. At the measurement points 32 of the measurement device 17, pre-reading measurement is performed in order in the respective measurement regions 41 to 43 of the shot region 15a. When the light irradiation region 30 reaches the shot region 15a, light irradiation to the light irradiation region 30 (that is, exposure in the light irradiation region 30) starts. Then, pre-reading measurement is sequentially performed in the respective measurement regions of the shot region 15a at the measurement points 32 of the measurement device 17, and driving of the substrate stage 16 is controlled based on the measurement values so that a surface height in the light irradiation region 30 is arranged at a target height. As described above, the target height can be the best focus position of the projection optical system 14.

When the light irradiation region 30 comes out the shot region 15a, light irradiation to the light irradiation region 30 (that is, exposure in the light irradiation region 30) ends. In response to the end of scanning exposure in the shot region 15a, the controller 20 moves step by step the substrate stage 16 in the X direction in order to perform scanning exposure in the next shot region 15c while decelerating the substrate stage 16 (substrate 15) moving in the direction F. Then, the controller 20 accelerates the substrate stage 16 in the direction R, and starts scanning exposure in the shot region 15c.

In recent years, along with a request for higher productivity, the exposure apparatus 100 needs to shorten the time taken for scanning exposure by increasing the scanning speed of the substrate 15. However, if the scanning speed of the substrate 15 is increased, the measurement time to perform pre-reading measurement (to be sometimes simply referred to as a measurement time hereinafter) by the measurement device 17 in each measurement region on the substrate 15 is shortened, and the measurement accuracy may decrease.

FIG. 4 is a graph showing the relationship between the scanning speed of the substrate 15, the measurement time, and the dispersion (measurement dispersion) of measurement values obtained by the measurement device 17. The measurement dispersion may be understood as a measurement error generated in measurement values of the measurement device 17, or the measurement reproducibility of the measurement device 17, and represents the measurement accuracy of the measurement device 17. FIG. 4 shows values of the scanning speed, measurement time, and measurement dispersion that are normalized based on condition A regarded as 1.0. With respect to condition A, the scanning speed of the substrate 15 is 1.2 times for condition B, 1.5 times for condition C, and 2.0 times for condition D. As is apparent from FIG. 4, as the scanning speed of the substrate 15 increases, the measurement time can shorten and the measurement dispersion (measurement error) can increase. For example, if the scanning speed of the substrate 15 is increased by 2.0 times in condition D with respect to condition A, the measurement time can shorten by 0.5 times and the measurement dispersion (measurement error) can increase by 1.4 times. That is, as the scanning speed of the substrate 15 is increased, the measurement accuracy of the measurement device 17 can decrease. The decrease in measurement accuracy causes a resolution failure owing to defocus.

As one of methods of improving the measurement accuracy of the measurement device 17, it is conceivable to control driving of the substrate stage 16 in the direction of height (Z direction) based on the measurement values of the surface heights of two or more measurement regions aligned in the scanning direction. By controlling driving of the substrate stage 16 based on the measurement values of the surface heights of two or more measurement regions, the measurement accuracy can be improved by the averaging effect even if the scanning speed of the substrate 15 increases to shorten the measurement time of each measurement region.

From this, the controller 20 according to this embodiment controls driving of the substrate stage 16 based on the measurement values of the surface heights of the first and second measurement regions obtained by the measurement device 17 so that the surface height of the first measurement region is arranged at a target height in exposure of the first measurement region. For example, the controller 20 sets a target driving position based on the measurement values of the surface heights of the first and second measurement regions obtained by the measurement device 17, and controls driving of the substrate stage 16 in the direction of height (Z direction) based on the target driving position. Here, the second measurement region is a measurement region for which the measurement device 17 performs pre-reading measurement after pre-reading measurement for the first measurement region and before exposure of the first measurement region. The target driving position is the target position (target height) of the substrate stage 16 for arranging the surface height of the first measurement region at a target height in exposure of the first measurement region.

An example in which driving of the substrate stage 16 is controlled based on only the measurement value of the surface height of the first measurement region in a conventional technique, and an example in which driving of the substrate stage 16 is controlled based on the measurement values of the surface heights of the first and second measurement regions in this embodiment will be explained below.

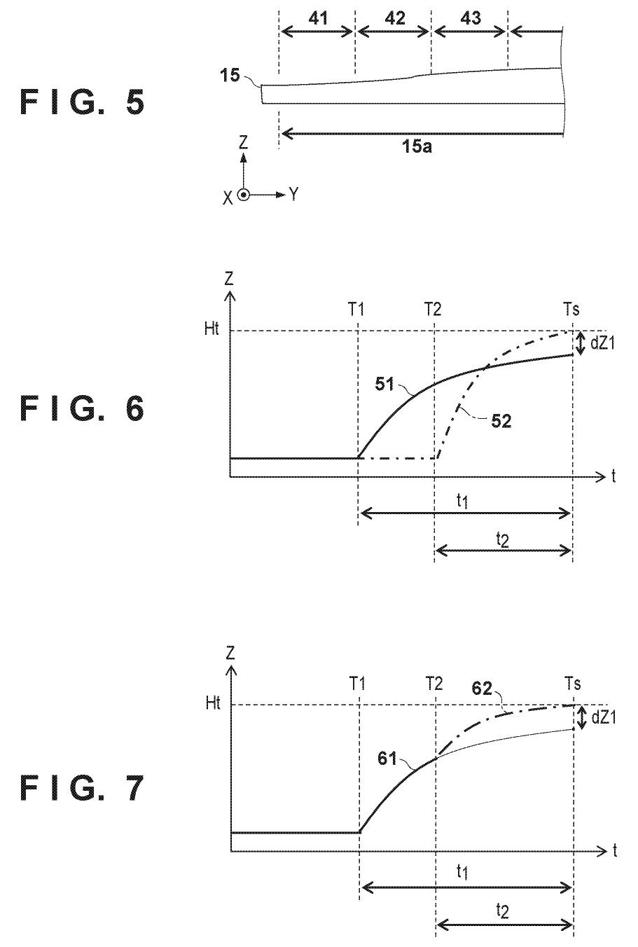

FIG. 5 shows the measurement regions 41 to 43 arrayed in the shot region 15a in the scanning direction of the substrate 15. In this embodiment, the measurement region 41 can correspond to the first measurement region, and the measurement region 42 can correspond to the second measurement region. FIG. 6 shows the trajectory of the surface height of the measurement region 41 in order to explain a control example of driving of the substrate stage 16 in the conventional technique and this embodiment. In FIG. 6, a trajectory 51 represents a control example of the conventional technique, and a trajectory 52 represents a control example of this embodiment.

In FIG. 6, "Ht" is a target height at which the measurement region 41 should be arranged in exposure of the measurement region 41. "T1" is time when pre-reading measurement of the measurement region 41 by the measurement device 17 (measurement points 32) ends. "T2" is time when pre-reading measurement of the measurement region 42 by the measurement device 17 (measurement points 32) ends. "Ts" is time when the light irradiation region 30 reaches the shot region 15a (measurement region 41). At the time Ts, light irradiation to the light irradiation region 30 starts, and exposure of the shot region 15a (measurement region 41) starts. Hence, driving of the substrate stage 16 needs to be controlled so that the surface height of the measurement region 41 is arranged at a target height till the time Ts.

First, a control example of the conventional technique in which driving of the substrate stage 16 is controlled based on the measurement value of the surface height of one measurement region 41 will be explained. When the measurement points 32 reach the measurement region 41, the measurement device 17 starts pre-reading measurement of the measurement region 41, and at the time T1 when the measurement points 32 come out the measurement region 41, ends the pre-reading measurement of the measurement region 41. In response to the end of the pre-reading measurement of the measurement region 41, the measurement device 17 outputs the average value of surface heights measured through the measurement region 41 as the "measurement value of the surface height of the measurement region 41 (to be also referred to as the measurement value of the measurement region 41 hereinafter)". Based on the measurement value of the measurement region 41 obtained from the measurement device 17, the controller 20 sets (determines or calculates) the target driving position of the substrate stage 16 for arranging the surface height of the measurement region 41 at a target height, and controls driving of the substrate stage 16 based on the target driving position.

As described above, as the scanning speed of the substrate 15 is increased, the measurement time of the measurement region 41 is shortened, and a large error may be generated in the measurement value of the measurement region 41. If the target driving position of the substrate stage 16 is set based on only the measurement value of the measurement region 41 including such an error, it may become difficult to arrange the surface height of the measurement region 41 at a target height in exposure (time Ts) of the measurement region 41, as represented by the trajectory 51 in FIG. 6. That is, a difference dZ1 may be generated between the surface height of the measurement region 41 and the target height in exposure (time Ts) of the measurement region 41. Depending on the size of the difference dZ1, a resolution failure may be caused by defocus.

Next, a control example of this embodiment in which driving of the substrate stage 16 is controlled based on the measurement values of the surface heights of the two measurement regions 41 and 42 will be explained. When the measurement points 32 reach the measurement region 41 (first measurement region), the measurement device 17 starts pre-reading measurement of the measurement region 41, and at the time T1 when the measurement points 32 come out the measurement region 41, ends the pre-reading measurement of the measurement region 41. In response to the end of the pre-reading measurement of the measurement region 41, the measurement device 17 outputs the average value of surface heights measured through the measurement region 41 as the "measurement value of the measurement region 41". When the measurement points 32 reach the measurement region 42 (second measurement region), the measurement device 17 starts pre-reading measurement of the measurement region 42, and at the time T2 when the measurement points 32 come out the measurement region 42, ends the pre-reading measurement of the measurement region 42. In response to the end of the pre-reading measurement of the measurement region 42, the measurement device 17 outputs the average value of surface heights measured through the measurement region 42 as the "measurement value of the surface height of the measurement region 42 (to be also referred to as the measurement value of the measurement region 42 hereinafter)".

Based on the measurement values of the measurement regions 41 and 42 obtained from the measurement device 17, the controller 20 sets (determines or calculates) the target driving position of the substrate stage 16 for arranging the surface height of the measurement region 41 at a target height. For example, the controller 20 sets the target driving position of the substrate stage 16 based on the average value of the measurement values of the measurement regions 41 and 42. Based on the target driving position, the controller 20 controls driving of the substrate stage 16.

As described above, according to this embodiment, the target driving position of the substrate stage 16 for arranging the surface height of the measurement region 41 at a target height is set based on the measurement value of the measurement region 41 and that of the measurement region 42 having undergone pre-reading measurement after the measurement region 41. By the averaging effect of the measurement values of the measurement regions 41 and 42, the surface height of the measurement region 41 can be accurately arranged at a target height in exposure (time Ts) of the measurement region 41, as represented by the trajectory 52 in FIG. 6. That is, the difference dZ1 between the surface height of the measurement region 41 and the target height in exposure (time Ts) of the measurement region 41 can be decreased, reducing a resolution failure caused by defocus.

### Second Embodiment

The second embodiment according to the present disclosure will be explained. The second embodiment basically inherits the first embodiment and can comply with the first embodiment, unless otherwise specified below.

In the first embodiment, driving of the substrate stage 16 starts based on the measurement values of the measurement regions 41 and 42 after the end of the pre-reading measurement of the measurement regions 41 and 42. In this case, however, the driving time of the substrate stage 16 is shortened, so it may become hard to arrange the surface height of the measurement region 41 at a target height till the time Ts when the light irradiation region 30 reaches the measurement region 41.

For example, when driving of the substrate stage 16 starts at the time T1 when pre-reading measurement of the measurement region 41 ends, the period in which the substrate stage 16 can be driven till the time Ts when the light irradiation region 30 reaches the measurement region 41 is "t₁", as indicated by the trajectory 51 in FIG. 6. To the contrary, when driving of the substrate stage 16 starts at the time T2 when pre-reading measurement of the measurement region 42 ends, the period in which the substrate stage 16 can be driven till the time Ts is "t₂", which is shorter than the period t₁, as indicated by the trajectory 52 in FIG. 6. In this case, it may become difficult to arrange the surface height of the measurement region 41 at a target height in the period t₂ from the time T2 to the time Ts depending on the scanning speed of the substrate 15 and the driving amount of the substrate stage 16, and a resolution failure may be caused by defocus.

To solve this, in response to pre-reading measurement of the first measurement region being performed, a controller 20 according to the second embodiment determines a target driving position based on the measurement value of the surface height of the first measurement region, and controls driving of a substrate stage 16 based on the target driving value. In response to pre-reading measurement of the second measurement region being further performed, the controller 20 sets again (updates) the target driving position based on the measurement value of the surface height of the first measurement region and that of the surface height of the second measurement region, and controls driving of the substrate stage 16 based on the target driving value after resetting. As described above, the second measurement region is a measurement region for which a measurement device 17 performs pre-reading measurement after pre-reading measurement for the first measurement region and before exposure of the first measurement region. The target driving position is the target position (target height) of the substrate stage 16 for arranging the surface height of the first measurement region at the target height in exposure of the first measurement region. Examples 1 to 3 in this embodiment will be described below.

### Example 1

In Example 1, an example in which pre-reading measurement of the first and second measurement regions is performed before exposure of the first measurement region will be explained. In Example 1, of a plurality of measurement regions 41 to 43 arrayed in a shot region 15a, as shown in FIG. 5, the measurement region 41 can correspond to the first measurement region, and the measurement region 42 can correspond to the second measurement region.

FIG. 7 shows the trajectory of the surface height of the measurement region 41 in order to explain a control example of driving of the substrate stage 16 in Example 1. In FIG. 7, "Ht", "T1", "T2", and "Ts" are the same as those in FIG. 6.

When measurement points 32 reach the measurement region 41 (first measurement region), the measurement device 17 starts pre-reading measurement of the measurement region 41, and at the time T1 when the measurement points 32 come out the measurement region 41, ends the pre-reading measurement of the measurement region 41. In response to the end of the pre-reading measurement of the measurement region 41, the measurement device 17 outputs the average value of surface heights measured through the measurement region 41 as the "measurement value of the measurement region 41". Based on the measurement value of the measurement region 41 obtained from the measurement device 17, the controller 20 sets the target driving position of the substrate stage 16 for arranging the surface height of the measurement region 41 at a target height, and controls driving of the substrate stage 16 based on the target driving position. The trajectory of the surface height of the measurement region 41 (first measurement region) in this case is represented as a trajectory 61 in FIG. 7.

In this manner, the target driving position set based on only the measurement value of the measurement region 41 is used before the end of pre-reading measurement of the measurement region 42 after the end of the pre-reading measurement of the measurement region 41. At this target driving position, it may be hard to arrange the surface height of the measurement region 41 at a target height in exposure (time Ts) of the measurement region 41, as represented by the trajectory 61 in FIG. 7. That is, a difference dZ1 may be generated between the surface height of the measurement region 41 and the target height in exposure (time Ts) of the measurement region 41. Depending on the magnitude of the difference dZ1, a resolution failure may be caused by defocus. To prevent this, in Example 1, in response to pre-reading measurement of the measurement region 42 being further performed, the target driving position is set again (updated) based on both the measurement values of the measurement regions 41 and 42.

When the measurement points 32 reach the measurement region 42 (second measurement region), the measurement device 17 starts pre-reading measurement of the measurement region 42, and at the time T2 when the measurement points 32 come out the measurement region 42, ends the pre-reading measurement of the measurement region 42. In response to the end of the pre-reading measurement of the measurement region 42, the measurement device 17 outputs the average value of surface heights measured through the measurement region 42 as the "measurement value of the measurement region 42". The controller 20 sets again the target driving position based on the measurement values of the measurement regions 41 and 42 obtained from the measurement device 17, and controls driving of the substrate stage 16 based on the target driving position. For example, the controller 20 sets again the target driving position based on the average value of the measurement values of the measurement regions 41 and 42, and controls driving of the substrate stage 16 based on the target driving position. The trajectory of the surface height of the measurement region 41 (first measurement region) in this case is represented as a trajectory 62 in FIG. 7.

In this fashion, after the end of pre-reading measurement of the measurement region 42, a target driving position set based on both the measurement values of the measurement regions 41 and 42 is used. That is, the target driving position can be accurately set by the averaging effect of the measurement values of the measurement regions 41 and 42. Since the substrate stage 16 is driven to a certain degree before the time T2 when pre-reading measurement of the measurement region 42 ends, the surface height of the measurement region 41 can be arranged accurately at the target height even in the short period t₂ from the time T2 to the time Ts. Therefore, the difference dZ1 between the surface height of the measurement region 41 and the target height, which may be generated in exposure (time Ts) of the measurement region 41, can be decreased, reducing a resolution failure caused by defocus.

### Example 2

In Example 2, an example in which pre-reading measurement of the first, second, and third measurement regions is performed before exposure of the first measurement region will be explained. The third measurement region is a measurement region for which the measurement device 17 performs pre-reading measurement after pre-reading measurement for the second measurement region and before exposure of the first measurement region. In Example 2, of the plurality of measurement regions 41 to 43 arrayed in the shot region 15a, as shown in FIG. 5, the measurement region 41 can correspond to the first measurement region, the measurement region 42 can correspond to the second measurement region, and the measurement region 43 can correspond to the third measurement region.

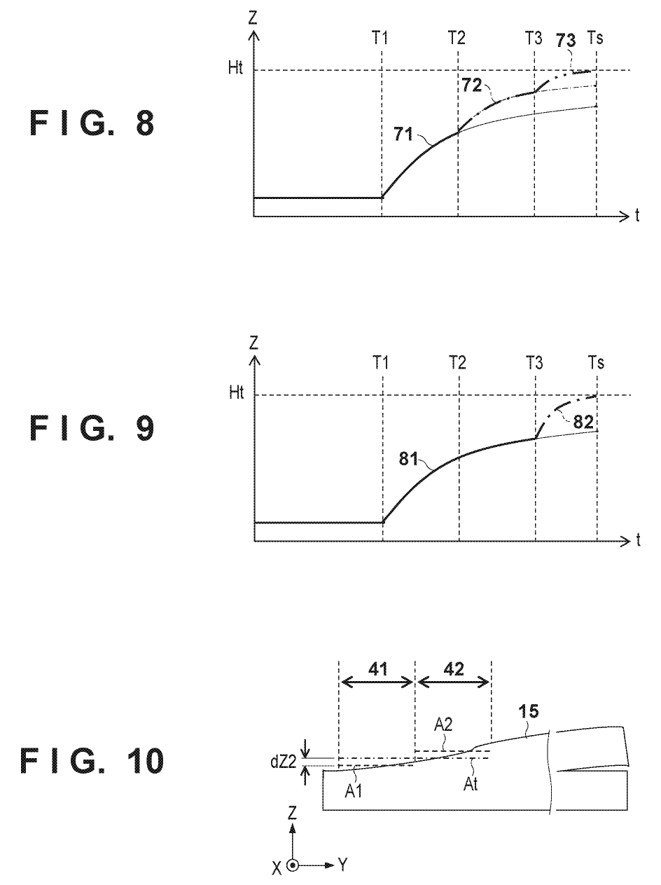

FIG. 8 shows the trajectory of the surface height of the measurement region 41 in order to explain a control example of driving of the substrate stage 16 in Example 2. In FIG. 8, "Ht", "T1", "T2", and "Ts" are the same as those in FIG. 6. In FIG. 8, "T3" is time when pre-reading measurement of the measurement region 43 by the measurement device 17 (measurement points 32) ends.

When the measurement points 32 reach the measurement region 41 (first measurement region), the measurement device 17 starts pre-reading measurement of the measurement region 41, and at the time T1 when the measurement points 32 come out the measurement region 41, ends the pre-reading measurement of the measurement region 41. In response to the end of the pre-reading measurement of the measurement region 41, the measurement device 17 outputs the average value of surface heights measured through the measurement region 41 as the "measurement value of the measurement region 41". Based on the measurement value of the measurement region 41 obtained from the measurement device 17, the controller 20 sets the target driving position of the substrate stage 16 for arranging the surface height of the measurement region 41 at a target height, and controls driving of the substrate stage 16 based on the target driving position. The trajectory of the surface height of the measurement region 41 (first measurement region) in this case is represented as a trajectory 71 in FIG. 8.

When the measurement points 32 reach the measurement region 42 (second measurement region), the measurement device 17 starts pre-reading measurement of the measurement region 42, and at the time T2 when the measurement points 32 come out the measurement region 42, ends the pre-reading measurement of the measurement region 42. In response to the end of the pre-reading measurement of the measurement region 42, the measurement device 17 outputs the average value of surface heights measured through the measurement region 42 as the "measurement value of the measurement region 42". The controller 20 sets again (updates) the target driving position based on the measurement values of the measurement regions 41 and 42 obtained from the measurement device 17, and controls driving of the substrate stage 16 based on the target driving position. For example, the controller 20 sets again the target driving position based on the average value of the measurement values of the measurement regions 41 and 42, and controls driving of the substrate stage 16 based on the target driving position. The trajectory of the surface height of the measurement region 41 (first measurement region) in this case is represented as a trajectory 72 in FIG. 8.

When the measurement points 32 reach the measurement region 43 (third measurement region), the measurement device 17 starts pre-reading measurement of the measurement region 43, and at the time T3 when the measurement points 32 come out the measurement region 43, ends the pre-reading measurement of the measurement region 43. In response to the end of the pre-reading measurement of the measurement region 43, the measurement device 17 outputs the average value of surface heights measured through the measurement region 43 as the "measurement value of the measurement region 43". The controller 20 sets again (updates) the target driving position based on the measurement values of the measurement regions 41, 42, and 43 obtained from the measurement device 17, and controls driving of the substrate stage 16 based on the target driving position. For example, the controller 20 sets again the target driving position based on the average value of the measurement values of the measurement regions 41, 42, and 43, and controls driving of the substrate stage 16 based on the target driving position. The trajectory of the surface height of the measurement region 41 (first measurement region) in this case is represented as a trajectory 73 in FIG. 8.

In this fashion, the number of measurement regions measured by the measurement device 17 before exposure of the measurement region 41 is increased, and every time pre-reading measurement of each measurement region ends, the target driving position is set again. This can decrease the difference dZ1 between the surface height of the measurement region 41 and the target height, which may be generated in exposure (time Ts) of the measurement region 41, and can reduce a resolution failure caused by defocus.

### Example 3

In Example 3, an example in which pre-reading measurement of the first, second, and fourth measurement regions is performed before exposure of the first measurement region will be explained. The fourth measurement region is a measurement region for which the measurement device 17 performs pre-reading measurement between the first measurement region and the second measurement region before exposure of the first measurement region. Note that the target driving position is not set again at the end of pre-reading measurement of the fourth measurement region in Example 3. In Example 3, of the plurality of measurement regions 41 to 43 arrayed in the shot region 15a, as shown in FIG. 5, the measurement region 41 can correspond to the first measurement region, the measurement region 42 can correspond to the fourth measurement region, and the measurement region 43 can correspond to the second measurement region.

FIG. 9 shows the trajectory of the surface height of the measurement region 41 in order to explain a control example of driving of the substrate stage 16 in Example 3. In FIG. 9, "Ht", "T1", "T2", and "Ts" are the same as those in FIG. 6. In FIG. 9, "T3" is time when pre-reading measurement of the measurement region 43 by the measurement device 17 (measurement points 32) ends.

When the measurement points 32 reach the measurement region 41 (first measurement region), the measurement device 17 starts pre-reading measurement of the measurement region 41, and at the time T1 when the measurement points 32 come out the measurement region 41, ends the pre-reading measurement of the measurement region 41. In response to the end of the pre-reading measurement of the measurement region 41, the measurement device 17 outputs the average value of surface heights measured through the measurement region 41 as the "measurement value of the measurement region 41". Based on the measurement value of the measurement region 41 obtained from the measurement device 17, the controller 20 sets the target driving position of the substrate stage 16 for arranging the surface height of the measurement region 41 at a target height, and controls driving of the substrate stage 16 based on the target driving position. The trajectory of the surface height of the measurement region 41 (first measurement region) in this case is represented as a trajectory 81 in FIG. 9.

When the measurement points 32 reach the measurement region 42 (fourth measurement region), the measurement device 17 starts pre-reading measurement of the measurement region 42, and at the time T2 when the measurement points 32 come out the measurement region 42, ends the pre-reading measurement of the measurement region 42. In response to the end of the pre-reading measurement of the measurement region 42, the measurement device 17 outputs the average value of surface heights measured through the measurement region 42 as the "measurement value of the measurement region 42". At the end of the pre-reading measurement of the measurement region 42, the target driving position is not set again.

When the measurement points 32 reach the measurement region 43 (second measurement region), the measurement device 17 starts pre-reading measurement of the measurement region 43, and at the time T3 when the measurement points 32 come out the measurement region 43, ends the pre-reading measurement of the measurement region 43. In response to the end of the pre-reading measurement of the measurement region 43, the measurement device 17 outputs the average value of surface heights measured through the measurement region 43 as the "measurement value of the measurement region 43". The controller 20 sets again (updates) the target driving position based on the measurement values of the measurement regions 41, 42, and 43 obtained from the measurement device 17, and controls driving of the substrate stage 16 based on the target driving position. For example, the controller 20 sets again the target driving position based on the average value of the measurement values of the measurement regions 41, 42, and 43, and controls driving of the substrate stage 16 based on the target driving position. The trajectory of the surface height of the measurement region 41 (first measurement region) in this case is represented as a trajectory 82 in FIG. 9.

Even the method of setting the target driving position of the substrate stage 16 in the above way can decrease the difference dZ1 between the surface height of the measurement region 41 and the target height, which may be generated in exposure (time Ts) of the measurement region 41, and can reduce a resolution failure caused by defocus.

### Third Embodiment

The third embodiment according to the present disclosure will be explained. The third embodiment basically inherits the first embodiment and can comply with the first embodiment, unless otherwise specified below. The second embodiment (Examples 1 to 3) may also be applied to the third embodiment.

FIG. 10 shows a plurality of measurement regions 41 and 42 arrayed in a shot region 15a in the scanning direction of a substrate 15. FIG. 10 may be understood as an enlarged view of a part including the measurement regions 41 and 42 that is extracted from FIG. 5. In FIG. 10, the ratio of a change of the surface height in the measurement regions 41 and 42 is larger than that in FIG. 5. In this embodiment, the measurement region 41 can correspond to the first measurement region, and the measurement region 42 can correspond to the second measurement region.

In FIG. 10, an average value A1 of surface heights measured through the measurement region 41 is represented as the "measurement value of the measurement region 41", and an average value A2 of surface heights measured through the measurement region 42 is represented as the "measurement value of the measurement region 42". FIG. 10 also shows an average value At of the measurement values of the measurement regions 41 and 42. The average value At may be understood as the average value of surface heights measured through the measurement regions 41 and 42.

Here, focusing on the measurement region 41, a difference dZ2 is generated between the measurement value A1 of the measurement region 41 and the average value At of the measurement regions 41 and 42. When the difference dZ2 affects the depth of focus of a projection optical system 14, defocus may be caused in exposure of the measurement region 41.

As one measure against a case where the difference dZ2 affects the depth of focus, whether to set again the target driving position of a substrate stage 16 is determined in accordance with the difference between the measurement value A1 of the measurement region 41 (first measurement region) and the measurement value A2 of the measurement region 42 (second measurement region). For example, when the difference between the measurement value A1 of the measurement region 41 and the measurement value A2 of the measurement region 42 is larger than a threshold, a controller 20 determines that the difference dZ2 between the measurement value A1 and the average value At affects the depth of focus of the projection optical system 14, and does not set again the target driving position of the substrate stage 16.

As another measure, the target driving position of the substrate stage 16 is set again based on results of weighting the measurement value A1 of the measurement region 41 (first measurement region) and the measurement value A2 of the measurement region 42 (second measurement region). For example, the controller 20 sets a weight w1 applied to the measurement value A1 of the measurement region 41 and a weight w2 applied to the measurement value A2 of the measurement region 42 so as to satisfy "w1 > w2", and calculates the average value At by the weighted average method. Based on the average value At, the controller 20 sets again the target driving position of the substrate stage 16.

Further, a case where the relationship between the scanning speed of the substrate 15, the measurement time in which pre-reading measurement is performed by a measurement device 17, and the measurement dispersion is known in advance, as shown in FIG. 4, will be considered. In this case, when the measurement time taken for each measurement region is larger than a time threshold, the target driving position of the substrate stage 16 may not be set again. The time threshold can be set to be a time in which the measurement accuracy of the measurement device 17 satisfies a required accuracy.

### Fourth Embodiment

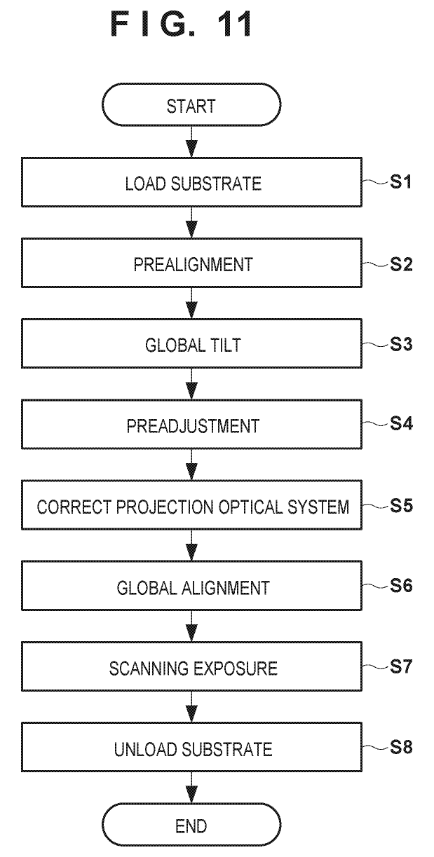

The fourth embodiment according to the present disclosure will be described. In this embodiment, exposure processing (exposure method) performed by an exposure apparatus 100 described above will be explained. FIG. 11 is a flowchart showing exposure processing according to this embodiment. Steps of this flowchart can be controlled by a controller 20.

In step S1, the controller 20 loads a substrate 15 onto a substrate stage 16 using a conveyance hand (not shown), and causes a chuck (not shown) to hold the substrate 15. In step S2, the controller 20 performs premeasurement and correction (prealignment) for global alignment to be executed in step S6 (to be described later). More specifically, the controller 20 measures and corrects the deviation amounts of the position and rotations of the substrate 15 using a low-power visual field alignment scope (not shown) so that the mark of the substrate 15 falls within the visual field of a high-power visual field alignment scope (not shown) used in global alignment.

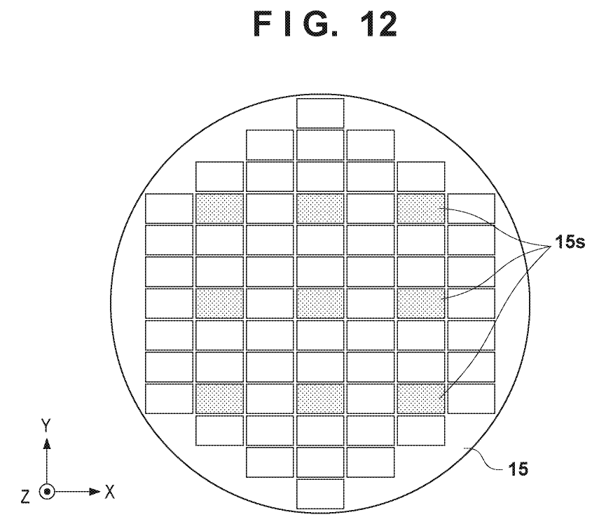

In step S3, the controller 20 measures surface heights of the substrate 15 at a plurality of portions using a measurement device 17, and calculates and corrects the tilt of the entire substrate 15 (global tilt). As an example, FIG. 12 is a plan view of the substrate 15 showing portions (sample shot regions 15s) subjected to surface height measurement. Then, in step S4, the controller 20 performs pre-adjustment for pre-reading measurement of scanning exposure in step S7 (to be described later). The pre-adjustment can include, for example, adjustment of the light amount of the measurement light source of the measurement device 17, and obtainment of a correction value for correcting an error dependent on a pattern structure on the substrate 15.

In step S5, the controller 20 calculates correction values for the tilt and field curvature of a projection lens in a projection optical system 14 and the like by using a light amount sensor and a reference mark (neither is shown) on the substrate stage 16, and a reference plate (not shown) on an original stage 13. More specifically, a change of the amount of exposure light when the substrate stage 16 is driven in the X, Y, and Z directions is measured by the light amount sensor. The deviation amount of the reference mark with respect to the reference plate is measured from the change amount of the light amount of the light amount sensor, and the correction amounts are calculated and corrected.

In step S6, the controller 20 measures an alignment mark on the substrate 15 using the high-power visual field alignment scope (not shown), and calculates the deviation amount of the entire substrate 15 and a deviation amount common to the shot regions. To measure the alignment mark precisely, the contrast of the alignment mark needs to be located at a best contrast position. Measurement of the best contrast position uses the measurement device 17 and an alignment scope. More specifically, the substrate stage 16 is driven to a predetermined height to measure the contrast by the alignment scope. At the same time, a step of measuring a surface height by the measurement device 17 is repeated several times. At this time, the measurement result of the contrast and the measurement result of the surface height are stored in the controller 20 in association with each other. From a plurality of obtained contrast measurement results, a surface height at which the contrast is highest is determined, and this surface height is determined as the best contrast position.

In step S7, the controller 20 performs scanning exposure with respect to a shot region 15a while performing pre-reading measurement by the measurement device 17 for respective measurement regions arrayed in the shot region 15a of the substrate 15. At this time, the method described in each of the first to third embodiments is applicable. Upon completion of the scanning exposure for all shot regions on the substrate 15, the process advances to step S8, and the controller 20 unloads the substrate 15 from the substrate stage 16. As a result, a series of exposure processes ends.

### Embodiment of Article Manufacturing Method

An article manufacturing method according to an embodiment of the present disclosure is suitable for manufacturing an article, for example, a microdevice such as a semiconductor device or an element having a microstructure. The article manufacturing method according to this embodiment includes an exposure step of performing scanning exposure of a substrate using the above-described exposure apparatus (exposure method), a processing step of processing the substrate having undergone the exposure step, and a manufacturing step of manufacturing an article from the substrate having undergone the processing step. The exposure step may be a step of forming a latent image on a photoresist applied to a substrate using the above-described exposure apparatus (exposure method). In this case, the processing step can include a step of developing the substrate on which the latent image pattern is formed. The manufacturing method further includes other known steps (oxidation, deposition, vapor deposition, doping, planarization, etching, resist removal, dicing, bonding, packaging, and the like). The article manufacturing method of this embodiment is more advantageous than conventional methods in at least one of the performance, quality, productivity, and production cost of the article.

### Other Embodiments

Embodiments of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-190074, filed on October 29, 2024, which is hereby incorporated by reference herein in its entirety.

What is claimed is:

1. An exposure apparatus that performs scanning exposure to a shot region on a substrate, comprising:
a stage configured to hold the substrate;
a measurement device configured to measure a surface height prior to exposure for each of a plurality of measurement regions arrayed in the shot region along a scanning direction of the substrate; and
a controller configured to control driving of the stage,
wherein the plurality of measurement regions include a first measurement region, and a second measurement region for which the measurement device measures a surface height after measurement of a surface height for the first measurement region and before exposure of the first measurement region, and
wherein the controller is configured to control, based on measurement values of surface heights for the first measurement region and the second measurement region obtained by the measurement device, driving of the stage to arrange the surface height of the first measurement region at a target height in exposure of the first measurement region.

2. The apparatus according to claim 1, wherein the controller is configured to set, based on the measurement values of the surface heights for the first measurement region and the second measurement region obtained by the measurement device, a target driving position of the stage for arranging the surface height of the first measurement region at the target height in exposure of the first measurement region, and control driving of the stage based on the target driving position.

3. The apparatus according to claim 2, wherein the controller is configured to:
in response to the measurement device measuring the surface height of the first measurement region, set the target driving position based on the measurement value of the surface height of the first measurement region; and
in response to the measurement device further measuring the surface height of the second measurement region, set again the target driving position based on the measurement values of the surface heights of the first measurement region and the second measurement region.

4. The apparatus according to claim 3, wherein in a case where a difference in the measurement value of the surface height between the first measurement region and the second measurement region is larger than a threshold, the controller does not set again the target driving position.

5. The apparatus according to claim 3, wherein
the plurality of measurement regions include a third measurement region for which the measurement device measures a surface height after measurement of a surface height for the second measurement region and before exposure of the first measurement region, and
the controller is configured to, in response to the measurement device further measuring the surface height of the third measurement region, set again the target driving position based on the measurement values of the surface heights for the first measurement region, the second measurement region, and the third measurement region.

6. The apparatus according to claim 3, wherein
the plurality of measurement regions include a fourth measurement region for which the measurement device measures a surface height between measurement of a surface height for the first measurement region and measurement of a surface height for the second measurement region and before exposure of the first measurement region, and
the controller is configured not to set again the target driving position in response to the measurement device measuring the surface height for the fourth measurement region, and in response to the measurement device measuring the surface height for the second measurement region, to set again the target driving position based on the measurement values of the surface heights for the first measurement region, the fourth measurement region, and the second measurement region.

7. The apparatus according to claim 2, wherein the controller is configured to set the target driving position based on an average value of the measurement value of the surface height of the first measurement region and the measurement value of the surface height of the second measurement region.

8. The apparatus according to claim 2, wherein the controller is configured to set the target driving position based on a result of weighting the measurement value of the surface height of the first measurement region and the measurement value of the surface height of the second measurement region.

9. The apparatus according to claim 1, wherein the measurement device is configured to output an average value of surface heights measured through the first measurement region, as the measurement value of the surface height for the first measurement region, and output an average value of surface heights measured through the second measurement region, as the measurement value of the surface height for the second measurement region.

10. The apparatus according to claim 1, further comprising a projection optical system configured to project a pattern image of an original onto the substrate,
wherein the target height is a best focus position of the projection optical system.

11. The apparatus according to claim 1, wherein the first measurement region is arranged at an end of the shot region where the scanning exposure starts.

12. An article manufacturing method comprising:
performing scanning exposure to a substrate using an exposure apparatus defined in claim 1;
processing the substrate to which the scanning exposure has been performed; and
manufacturing an article from the substrate which has been processed.

13. An exposure method of performing scanning exposure to a shot region on a substrate, comprising:
measuring a surface height prior to exposure for each of a plurality of measurement regions arrayed in the shot region along a scanning direction of the substrate; and
controlling driving of a stage configured to hold the substrate,
wherein the plurality of measurement regions include a first measurement region, and a second measurement region for which a surface height is measured after measurement of a surface height for the first measurement region and before exposure of the first measurement region, and
wherein in the controlling, based on measurement values of surface heights for the first measurement region and the second measurement region obtained in the measuring, driving of the stage is controlled to arrange the surface height of the first measurement region at a target height in exposure of the first measurement region.
